(19) United States
(12) Patent Application Publication
(10) Pub. No.: US 2026/0129812 A1
(43) Pub. Date: May 7, 2026

(54) BRIDGED PIN ARRAY FOR IMPROVED STIFFNESS

(71) Applicants: DENSO International America, Inc., Southfield, MI (US); DENSO CORPORATION, Kariya (JP)

(72) Inventor: Alexander PLEDGER, Southfield, MI (US)

(21) Appl. No.: 19/088,366

(22) Filed: Mar. 24, 2025

Related U.S. Application Data
(60) Provisional application No. 63/716,940, filed on Nov. 6, 2024.

(51) Int. Cl. H05K 7/20

(52) U.S. Cl. CPC H05K 7/209

(57) ABSTRACT

A heat sink includes a base extending from a first end to a second end and a plurality of pin fins extending from the base and arranged in a number of columns including a first column and a second column. Each pin fin includes a lower portion at or near the base and an opposing top portion spaced apart from the base. A plurality of bridged ribs includes a first plurality of bridged ribs, wherein the first plurality of bridged ribs each connect the top portion of one of the pin fins in the first column with the top portion of one of the pin fins in the second column.

### CROSS-REFERENCE TO RELATED APPLICATION

The present disclosure claims the benefit of Provisional Patent Application No. 63/716,940 filed on Nov. 6, 2024 and entitled “BRIDGED PIN ARRAY FOR IMPROVED STIFFNESS”, the contents of which are incorporated by reference in its entirety.

### TECHNICAL FIELD

The present disclosure relates to pin fins for a heat sink for improving stiffness of the heat sink. In embodiments, the present disclosure relates to a heat sink with an array of pin fins, wherein the certain pin fins are connected by bridges.

### BACKGROUND

The performance, lifespan, and safety of many electrical components are dependent on the temperature at which the electrical components operate and a build-up of heat can negatively affect these elements. The temperature of the electrical component may be affected by heat generated from the electrical component or its surrounding environment. Heat sinks are used to dissipate heat from electrical components or other heat-generating devices and prevent the negative effects from a build-up of heat. Some heat sinks use pin fins that extend outward from a base that is in thermal communication with the electrical component. As fluids (e.g., air, water, or the like) flow along the heat sink through the pin fins, the pin fins transfer the heat from the electrical component to the fluid, cooling the electrical component.

One method of improving heat transfer is to reduce the thickness of the base of the heat sink. However, a reduction in the thickness of the base is limited by an overall stiffness of the heat sink, which ensures proper thermal contact with the electrical component and ensures no leakages during operation.

### SUMMARY

According to an embodiment, a heat sink comprises a base extending from a first end to a second end and a plurality of pin fins extending from the base and arranged in a number of columns including a first column and a second column. Each pin fin includes a lower portion at or near the base and an opposing top portion spaced apart from the base. A plurality of bridged ribs includes a first plurality of bridged ribs, wherein the first plurality of bridged ribs each connect the top portion of one of the pin fins in the first column with the top portion of one of the pin fins in the second column.

According to an embodiment, a heat sink comprises a base extending from a first end to a second end and a plurality of pin fins extending from the base wherein each pin fin includes a lower portion at or near the base and an opposing top portion spaced apart from the base. A plurality of bridges are angled to align with a fluid flow direction from the first end to the second end for minimizing effects on a pressure drop of the heat sink. A first column of the pin fins adjacent the first end, wherein the top portions of at least two of the pin fins in the first column are connected by a first of the plurality of bridges. A second column of the pin fins adjacent the second end, wherein the top portions of at least two of the pin fins in the second column are connected by a second of the plurality of bridges.

According to an embodiment, a method of manufacturing a heat sink, the method comprising forming a plurality of pin fins that extend from a base of the heat sink, wherein each pin fin includes a lower portion at or near the base and an opposing top portion spaced apart from the base; forming a plurality of bridged ribs using an additive manufacturing process, wherein each of the plurality of bridged ribs each connect the top portion of one of the plurality of pin fins to the top portion of another of the plurality of pin fins; and wherein the plurality of bridged ribs increase an overall stiffness of the heat sink to resists bending and torsional moments.

### BRIEF DESCRIPTION OF THE DRAWINGS

FIG. 1 is a top view of a heat sink including a plurality of bridges connecting a plurality of pin fins, according to a number of embodiments of the present disclosure;

FIG. 2 is a cross-sectional view of the heat sink, wherein the plurality of bridges extend between top portions of the plurality of pin fins, according to an embodiment of the present disclosure;

FIGS. 3A & 3B are enlarged, cross-sectional views of the heat sink shown in FIG. 1, wherein the plurality of bridges are angled to align with a flow direction of a fluid, according to an embodiment of the present disclosure;

FIG. 3C is an enlarged, cross-sectional views of the heat sink shown in FIG. 1 wherein pin fins of at least two columns are connected by the plurality of pin fins, according to an embodiment of the present disclosure; and

FIG. 3D is an enlarged top view of the heat sink shown in FIG. 1 showing the plurality of bridges connecting pin fins in a plurality of columns, according to an embodiment of the present disclosure.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

Inverter cards are electronic components commonly used to convert direct current (DC) to alternating current (AC) in various applications, such as powering AC motors, lighting, and devices from a DC source. These cards are integral to power electronics systems, including renewable energy setups (e.g., solar power systems), electric vehicles, and uninterruptible power supplies (UPS). Inverter cards typically include several heat-generating components, such as power transistors, driver circuits, capacitors, and inductors, as well as integrated circuits (ICs) that perform control, processing, and support functions.

During operation, the power transistors and other components on an inverter card can generate significant heat, necessitating the use of heat sinks to prevent overheating and ensure reliable performance. Heat sinks, typically made from thermally conductive materials such as aluminum or copper, transfer heat away from the components to the surrounding air or a fluid (gas or liquid) passing through pin fins protruding from a base of the heat sink. Some heat sink include a wall opposing the base that defines an enclosed fluid flow path in which the fluid is cycled through the pin fins from an inlet to an outlet. Heat is transferred to the heat sink by direct contact with the component or via thermally conductive pads or pastes. Maintaining such contact is important to preserve an efficient transfer of heat to the heat sink and avoid unanticipated hot spots from forming.

One means of improving the overall heat transfer of a heat sink is by reducing a thickness of a base of the heat sink to reduce the conductive thermal resistance. However, a reduction in the base thickness is limited by an overall stiffness of the heat sink. The stiffness of a heat sink is important for maintaining consistent and efficient thermal contact with a heat source (e.g., a inverter card), even under mounting stress (e.g., deformation of the heat sink by the weight of mounting hardware, etc.) and thermal expansion/contraction (e.g., deformation such as bending, buckling, or warping due to the expansion and contraction of the heat sink as a result of temperature fluctuations during operation and the material composition of the heat sink). The stiffness of the heat sink further aids in preventing any fluid from leaking out of the heat sink during operation. Accordingly, there is a need for improved heat sink designs that enhance heat dissipation without jeopardizing stiffness.

Therefore, according to various embodiments disclosed herein, the present disclosure provides a heat sink featuring bridges or bridge segments between pin fins to increase the stiffness of the heat sink. The bridges may be added to select pin fins and may be designed to have a minimal effect on the pressure drop across the heat sink. Such effects on the pressure drop are outweighed by the reduction in the conductive thermal resistance as a result of decreasing the thickness of the base of the heat sink. Consequently, the embodiments disclosed herein allow for heat sink designs with improve heat transfer without increasing risks of damage, leaks, loss of contact, or the like.

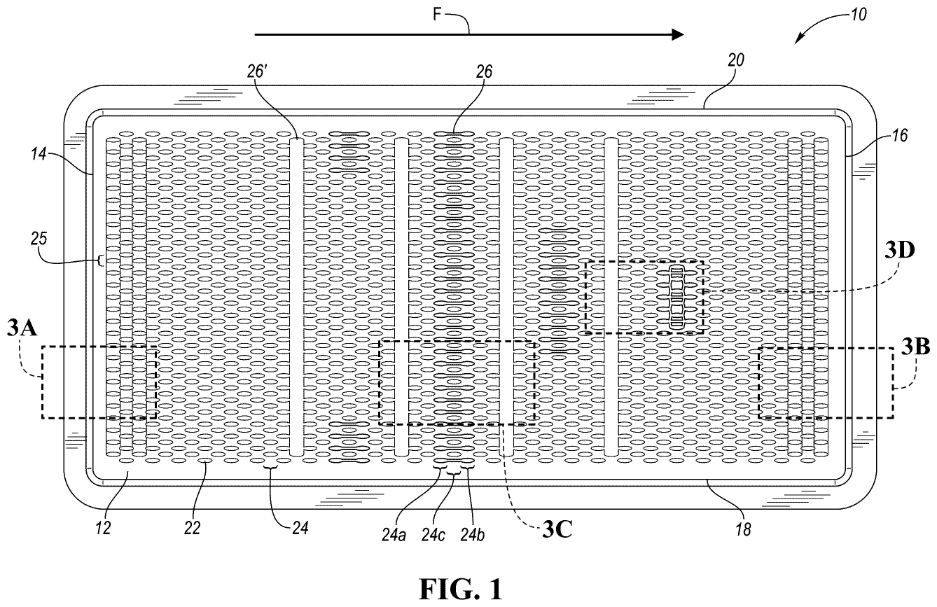

Referring to FIG. 1, a heat sink 10 for dissipating heat from a heat-generating device (e.g., an electrical or computer component, an inverter card, a power card, or the like) is illustrated, according to an embodiment of the present disclosure. The heat sink includes a substrate or base 12 surrounded by an outer plate. The heat sink 10 may be attached to the heat-generating device via the outer plate, a thermal paste, a connecting component between the heat sink 10 and the device, or the like. The heat-generating device may be attached to a bottom side of the heat sink which is not visible from the top view shown in these Figures. The heat sink 10 may also be connected to a housing (e.g., via the outer plate) that encloses the heat sink 10 for containing and exposing the base 12 to a fluid, such as water, air, refrigerant, oil, dielectric fluid, or some other non-conductive thermal transfer fluid, or the like. The fluid is conveyed (by forced or natural convection) through the heat sink 10 from a first end 14 (also referred to as an inlet region) to a second end 16 opposite the first end 14 (also referred to as an outlet region), such that the fluid travels along the fluid flow direction indicated by arrow F. The fluid flow direction is a generally longitudinal direction from the first end 14 to the second end 16. In some embodiments, the heat sink 10 includes a first side 18 and a second side 20 opposite the first side 18, wherein the first side 18 and the second side 20 are connected to the first end 14 and the second end 16. The first end 14 and the second 16 may define a length of the heat sink 10 and the first side 18 and the second side 20 may define a width of the heat sink 10.

The heat sink 10 includes pin fins 22 (e.g., pins, fins, projections, protrusions, or the like) that extend outwardly from the base 12. The pin fins 22 may be disposed along the base 12 from the first end 14 to the second end 16 and/or from the first side 18 to the second side 20. The pin fins 22 may be arranged in an array according to any suitable arrangement or pattern. For example, the pin fins 22 may be arranged in a number of rows 25 (e.g., from the first end 14 to the second end 16) and columns 24 (e.g., from the first side 18 to the second side 20), wherein the pin fins 22 of adjacent columns 24 are of centered relative to each other to form a staggered arrangement. Likewise, the columns 24 of the pin fins 22 may be arranged in line with each other, or a combination or sub-combination thereof.

In present disclosure, the array of pin fins 22 is shown to include the pin fins 22 in a staggered arrangement from the first end 14 to the second end 16 of the heat sink. However, it is considered to be within the scope of this disclosure that the array of pin fins 22 may include one or more rows 25 and/or columns 24 and may include separate or discontinuous groupings of pin fins 22 (e.g., a first collection of pin fins 22 located adjacent the first end 14 and a second collection of pin fins 22 located adjacent the second end 16, wherein a space or void is present between the first and second collection of pin fins 22). Similarly, the heat sink 10 of the present disclosure is shown to be rectilinear as defined by the first and second ends 14, 16 and the first and second end 18, 20. However, other shapes or designs for the heat sink 10 are considered to be within the scope of this disclosure (e.g., curvilinear, U-shaped, or other polygonal or maze-like designs). Furthermore, in the present disclosure, the pin fins 22 are shown to have an elliptical shape, however, other shapes and/or combination of shapes may be used (e.g., a circular, airfoil, rectangular, pyramidal, or other polygonal shapes, or the like).

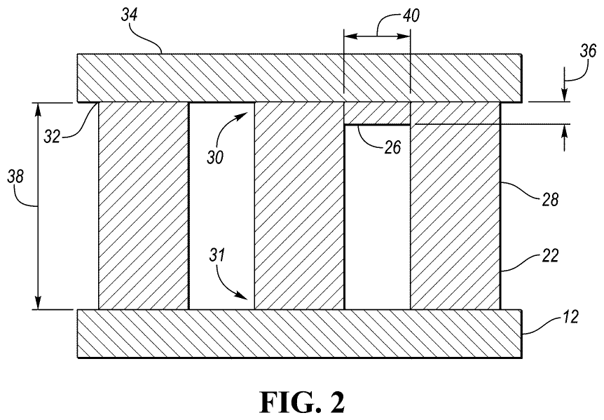

Referring to FIGS. 1 and 2, in an embodiment the heat sink 10 includes a bridged 26 (bridged ribs, bars, or the like) that forms a connection between two pin fins 22 and extends therebetween. The heat sink 10 may include a plurality of bridges 26 for connecting a corresponding number or pairs of the pin fins 22. Joining the pin fins 22 together via the plurality of bridges 26 increase an overall stiffness of the heat sink 10, allowing the heat sink 10 to have an increased resistance to bending and torsional moments, which may occur during operation (thermal expansion and contraction, mounting stress, vibrations, or the like) and at other times (e.g., during transportation of the heat sink 10 or the electrical component to which the heat sink 10 is connected to).

In an embodiment, the bridge 26 may extend from side surfaces 28 of the pin fins 22 at or adjacent to a top portion 30 of the pin fins 22. The plurality of bridges 26 may each connect the top portion 30 of one of the pin fins 22 with the top portion 30 of another pin fin 22. A bottom portion 31 of the pin fins 22 is located at or near the base 12 and the top portion 30 is spaced apart from the base 12. In some embodiments, the bridge 26 is substantially in line with or flush to a top surface 32 of the connected pin fins 22, such that the bridge 26 is in contact with a wall/surface 34 opposite the base 12 (e.g., an upper component of the heat sink 10, electrical component, other mounting hardware, or the like, defining an enclosed chamber or fluid path within in which the cooling fluid may flow through without leaking). In this way, an increase in pressure drop—as a result of the plurality of bridges 26—is minimized due to the cooling fluid having a lower velocity region located near the plurality of bridges 26 (e.g., the cooling fluid has a laminar flow, laminar sublayer flow, or the like).

As shown in FIG. 2, the plurality of bridges 26 have a bridge thickness or height 36 and the pin fins 22 have a pin fin height 38. In an embodiment, the bridge thickness 36 may be less than 1-5%, 5-10%, 10-15%, 15-20% (or a combination or sub-combination thereof) of the pin fin height 38 for the pin fins 22 joined by the plurality of bridges 26. In some embodiments, the bridge thickness 36 may vary for the plurality of bridges 26. For example, a plurality of pin fins 22 in a first region may have a greater bridge thickness 36 than a plurality of pin fins 22 in a second region on account of the first region requiring an increased localized stiffness and/or the first region having a greater effect on the overall stiffness of the heat sink 10 whereby the plurality of pin fins 22 in the second region can have a lesser bridge thickness 36, leading to a minimization an increase in pressure drop. The first region may between the first end 14 and the second end 16, adjacent to the first end 14 and/or the second end 16, or the like. The first region may also be between or extend from the first side 18 and the second side 20, or the like. Thus, the overall stiffness and stiffness in certain locations of the heat sink 10 can be affected by the number and placement of the plurality of bridges 26.

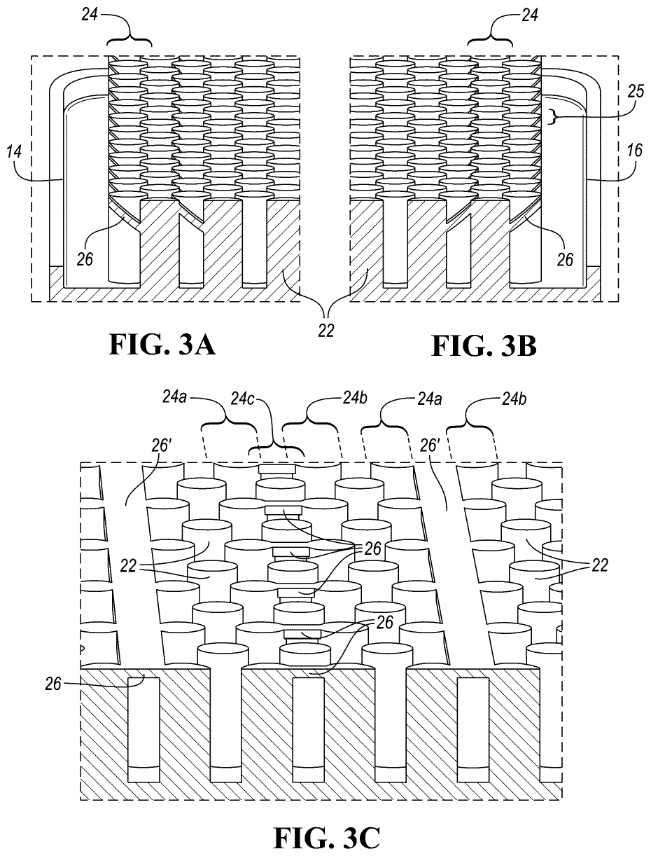

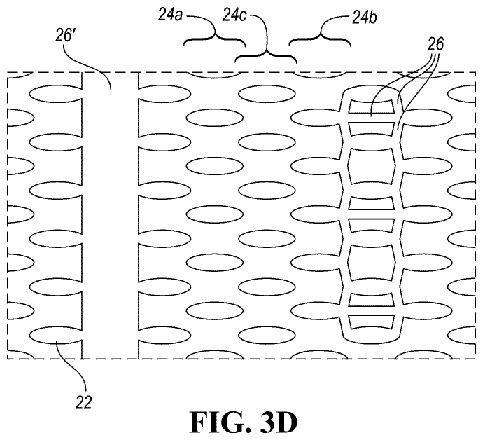

Referring to FIGS. 1 and 3A-3B, in an embodiment pin fins 22 in columns 24 adjacent the first end 14 and/or the second end 16 may be connected by the plurality of bridges 26 (within the respective columns 24). The plurality of bridges 26 may be aligned with a fluid flow direction so as to minimize pressure drop. For example, the plurality of bridges 26 may be angled so that the profile of the plurality of bridges results in minimal turbulence as the fluid enters and exits the heat sink 10. In the present disclosure, the plurality of bridges 26 are shown to have a substantially rectilinear shape, however, the plurality of bridges 26 may include other shapes or a combination of shapes and profiles (e.g., elliptical, airfoil, curvilinear, or the like).

Referring to FIG. 1, and 3C-3D, in an embodiment wherein the pin fins 22 of at least two columns 24 may be connected by the plurality of bridges 26. For example, the plurality of bridges 26 may connect pairs of the pin fins 22 in a first column 24a and a second column 24b. The first column 24a and the second column 24b may be spaced apart from or adjacent to the first end 14 and/or the second end 16. In some embodiments, the plurality of bridges 26 connects all of the pin fins 22 in the first column 24a and the second column 24b (i.e., the plurality of bridges 26 joins the top portions of the pin fins 22 in the first column 24a and the second column 24b from adjacent the first side 18 to adjacent the second side 20). In some embodiments, the plurality of bridges 26 may join only some of the top portions of the pin fins 22 in the first and second columns 24a, 24b. For example, as shown in FIG. 1, the plurality of bridges 26 may connect some of the pin fins 22 adjacent the first side 18 and/or the second side 20, between and spaced apart from the first side 18 and the second side 20, or the like, or a combination or sub-combination thereof. In this way, the selective use of a limited number of the plurality of bridges 26 can be implemented to increase the localized stiffness of key areas on the heat sink 10 (e.g., corners, sides, ends, center, or the like, or a combination or sub-combination thereof), resulting in a greater overall stiffness and/or rigidity of the heat sink 10.

In an embodiment, a third column 24c of pin fins 22 is positioned between the first column 24a and the second column 24b, wherein the pin fins 22 of the third column 24c may be off-centered or staggered relative to the pin fins 22 of the first and second columns 24a, 24b. The plurality of bridges 26 may connect respective pairs of adjacent pin fins 22 in the first, second, and third columns 24a, 24b, 24c. For example, as shown if FIG. 3C, a bridge 26′ may connect opposing pairs of pin fins 22 in the first and second columns 24a, 24b, and adjacent pin fins 22 in the third column 24c. The bridge 26′ may resemble or be a single bridge 26′ connecting all of the pin fins 22 in the first, second, and third columns 24a, 24b, 24c. In other examples, as shown in FIG. 3D, a plurality of bridges 26 may form a lattice-like network, wherein the plurality of bridges 26 form discrete connections between the pin fins 22 in the first column 24a and the second column 24b, the pin fins 22 in the first column 24a and the third column 24c, and/or the pin fins 22 in the second column 24b and the third column 24c, or the like, or a combination or sub-combination thereof. The lattice of the plurality of bridges 26 may include a repeatable pattern and/or include discrete connections between the pin fins 22 as needed in particular locations on the heat sink 10 to improve the stiffness of the heat sink 10 without greatly influencing pressure drop.

As shown in FIG. 2, the plurality of bridges 26 have a bridge length 40. The bridge length 40 may be a distance between two pin fins 22 and may vary amongst the plurality of bridges 26 in accordance with the pin fins 22 being connected by the plurality of bridges 26.

In embodiments, the plurality of bridges 26 may connect pin fins 22 of the same or adjacent row(s) 25 in the same manner as described above for pin fins 22 of the same or different columns 24. In some embodiments, the heat sink 10 may include a plurality of bridges 26 connecting pin fins 22 in columns 24 and rows 25.

Due to the properties, placement, and arrangement of the plurality of bridges 26, only a certain number of pin fins 22 may be connected by the plurality of bridges 26. For example, the plurality of bridges 26 may be provided such that less than 1-5%, 5-10%, 10-15%, 15-20%, 20-30, 30-50% (or a combination or sub-combination thereof) of the pin fins 22 are connected by the plurality of bridges 26. In certain embodiments, only 10% of the pin fins 22 are connected via the plurality of bridges 26. Similarly, depending on the design or operational needs of the heat sink 10, the plurality of bridges 26 may be provided in less than 1-5%, 5-10%, 10-15%, 15-20% (or a combination or sub-combination thereof) of a number of columns 24 of pin fins 22. In other words, the inclusion of only a limited number of plurality of bridges 26 may be required to achieve a desired stiffness if selectively positioned and arranged. As an example, for a heat sink 10 having one hundred columns 24, only five columns 24 may include and/or be connected by the plurality of bridges 26.

As discussed above, the overall stiffness and localized stiffness of the heat sink 10 can be affected by the number, placement, angle, bridge thickness 36, etc. of the plurality of bridges 26. However, traditional methods of manufacturing heat sinks 10 (e.g., casting or forging) are limited and may not be able to effectively and efficiently manufacturing heat sinks 10 having a plurality of bridges 26. One method of manufacturing a heat sink 10 having a plurality of bridges 26 includes additive manufacturing (e.g., 3D-printing, metal power bed fusion, direct metal laser sintering, electron beam melting, selective laser sintering, binder jetting, or other laser beam power bed fusion methods, or the like). Additive manufacturing allows for a precise, controlled, repeatable method of forming the plurality of bridges 26 such that the shape, size, position, and arrangement of the plurality of bridges 26 are consistent and result in an increased stiffness of the heat sink 10 so as to aid in maintaining contact between the heat sink 10 and an heat generating component and preventing fluid leaks.

The pin fins 22 and bridges 26 may be composed of any material capable of transferring heat from the device to the fluid (e.g., copper, aluminum, steel, a metal alloy, or the like). The plurality of bridges 26 may be formed so as to be integral with the pin fins 22. In some embodiments, the plurality of bridges 26 may connect a pin fin 22 to a boundary wall defined by the first end 14, second end 16, first side 18, second side 20, or the like, of the heat sink 10.

As discussed above, the plurality of bridges 26 may be used to improve the overall and/or localized stiffness of the heat sink 10, which in turn allows the thickness of the base 12 to be reduced or minimalized. A reduction in the thickness of the base 12 reduces conductive thermal resistance and improves the overall heat transfer of the heat sink 10. Accordingly, embodiments of the present disclosure may be used to improve heat transfer of a variety of heat sinks.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A heat sink comprising:
a base extending from a first end to a second end;
a plurality of pin fins extending from the base and arranged in a number of columns including a first column and a second column, wherein each pin fin includes a lower portion at or near the base and an opposing top portion spaced apart from the base; and
a plurality of bridged ribs including a first plurality of bridged ribs, wherein the first plurality of bridged ribs each connect the top portion of one of the pin fins in the first column with the top portion of one of the pin fins in the second column.

2. The heat sink of claim 1 wherein the plurality of bridged ribs have a thickness of less than 10% of a height of the plurality of pin fins of the first column and the second column.

3. The heat sink of claim 1 wherein the plurality of bridged ribs are 3D-printed bridged ribs.

4. The heat sink of claim 1 wherein the plurality of bridged ribs are provided in less than 10% of the number of columns of the plurality of pin fins.

5. The heat sink of claim 1 wherein the first plurality of bridged ribs only connect some of the top portions of some of the pin fins in the first column and the second column.

6. The heat sink of claim 1 wherein the plurality of bridged ribs increase an overall stiffness of the heat sink to resists bending and torsional moments.

7. The heat sink of claim 1 wherein the base extends from a first side and a second side opposite the first side, wherein the columns of the plurality of pin fins extend from adjacent the first side to adjacent the second side; and
wherein the top portions of the pin fins in the first column are connected to the top portions of the pin fins in the second column by the first plurality of bridged ribs.

8. The heat sink of claim 1 wherein a plurality of pin fins in a third column are located between the first column and the second column in a staggered arrangement.

9. The heat sink of claim 8 wherein a third column of the pin fins is adjacent the first end, and wherein the top portions of the pin fins in the third column are connected by a second plurality of bridges.

10. A heat sink comprising:
a base extending from a first end to a second end;
a plurality of pin fins extending from the base wherein each pin fin includes a lower portion at or near the base and an opposing top portion spaced apart from the base;
a plurality of bridges angled to align with a fluid flow direction from the first end to the second end for minimizing effects on a pressure drop of the heat sink;
a first column of the pin fins adjacent the first end, wherein the top portions of at least two of the pin fins in the first column are connected by a first of the plurality of bridges; and
a second column of the pin fins adjacent the second end, wherein the top portions of at least two of the pin fins in the second column are connected by a second of the plurality of bridges.

11. The heat sink of claim 10 wherein the plurality of bridges are 3D-printed bridges.

12. The heat sink of claim 10 wherein the plurality of bridges are provided with a thickness of less than 10% of a height of the plurality of pin fins connected by the plurality of bridges.

13. The heat sink of claim 10 wherein the base extend from a first side to a second side, wherein in the first column and the second column of pin fins extend from adjacent the first side to adjacent the second side; and
wherein the top portions of the pin fins in the first column are connected by the first plurality of bridges or the second column are connected by the second plurality of bridges.

14. The heat sink of claim 10 further comprising:
a third column of the pin fins and a fourth column of pin fins spaced apart from the first end and the second end, wherein a third of the plurality of bridges each connect the top portion of one of the pin fins in the third column with the top portion of one of the pin fins in the fourth column.

15. The heat sink of claim 14 wherein in the plurality of pin fins connected by the plurality of bridges are provided in less than 10% of a number of the plurality of pins.

16. A method of manufacturing a heat sink, the method comprising:
forming a plurality of pin fins that extend from a base of the heat sink, wherein each pin fin includes a lower portion at or near the base and an opposing top portion spaced apart from the base;
forming a plurality of bridged ribs using an additive manufacturing process, wherein each of the plurality of bridged ribs connect the top portion of one of the plurality of pin fins to the top portion of another of the plurality of pin fins; and
wherein the plurality of bridged ribs increase an overall stiffness of the heat sink to resists bending and torsional moments.

17. The method of claim 16 wherein plurality of pin fins are arranged in a number of columns, and the plurality of bridged ribs each connect a pair of the plurality of pin fins in a first column and a second column.

18. The method of claim 17 wherein the plurality of bridged ribs are provided in less than 10% of the number of columns of the plurality of pin fins.

19. The method of claim 16 wherein the plurality of bridges are provided with a thickness of less than 10% of a height of the plurality of pin fins connected by the plurality of bridges.

20. The method of claim 16 wherein:
a plurality of pin fins adjacent a first end of the heat sink are connected by the plurality of bridges;
a plurality of pin fins adjacent a second end of the heat sink are connected by the plurality of bridged ribs;
wherein the plurality of bridged ribs connecting the plurality of pin fins adjacent the first end and the second end are angled to align with a fluid flow direction for minimizing effects on a pressure drop of the heat sink; and
a plurality of pin fins in a first column and a second column are connected by the plurality of bridged ribs, wherein the first column and the second column are spaced apart from the first end and the second end.
